(19) United States
(12) Patent Application Publication
(10) Pub. No.: US 2011/0168235 A1
(43) Pub. Date: Jul. 14, 2011

(54) APPARATUS AND METHOD FOR GENERATING ELECTRICITY USING PHOTOVOLTAIC PANELS

(75) Inventors: Marco Rosa Clot, Cascina (IT); Paolo Rosa Clot, Cascina (IT); Sandro Carrara, Cascina (IT)

(73) Assignee: SCIENZA INDUSTRIA TECNOLOGIA S.R.L., I-56023 CASCINA (PISA) (IT)

(21) Appl. No.: 13/061,365

(22) PCT Filed: Sep. 3, 2009
(86) PCT No.: PCT/IB09/53852

§ 371 Date: Feb. 28, 2011

(30) Foreign Application Priority Data
Sep. 5, 2008 (IT) PI2008A000088

(51) Int. Cl. H01L 31/052

(52) U.S. Cl. 136/246

(57) ABSTRACT

An apparatus (1) for generating electricity using photovoltaic panels (2) comprises a panel (2) mounting structure (4) adapted to position the panels in a body of water in such a way that the top faces (3) of the panels (2) designed to receive the solar radiation are operatively covered by a layer of water of predetermined depth. A method for generating electricity using photovoltaic panels (2) comprises preparing a panel (2) mounting structure (4) and positioning the structure (4) in a body of water in such a way that the top faces (3) of the panels (2) designed to receive the solar radiation are operatively covered by a layer of water of predetermined thickness.

### TECHNICAL FIELD

This invention relates to an apparatus and a method for generating electricity using photovoltaic panels.

### BACKGROUND ART

The typical system for generating electricity from solar energy consists of photovoltaic solar cells.

The solar photovoltaic cells are made from semiconductor systems which, thanks to the photoelectric effect, can convert the sun's rays that strike the surface of the semiconductor into electricity. Each photon that strikes the surface of the semiconductor produces a quantum of current.

The performance of all systems that generate electricity using photovoltaic cells tends to drop off with increase in temperature, in particular, in the temperature of the semiconductor material.

For example, the efficiency of monocrystalline silicon drops from 12-15% at 25° C. to 9-12% at 70° C.

One method proposed by the prior art to increase the efficiency of photoelectric panel is to create a forced flow of fluid (for example, air or water) to lower the temperature of the photovoltaic cells and, at the same time, heat the fluid itself, thus constituting a combined heat and power system.

Thus, the prior art comprises technical solutions that combine the production of heat energy with that of electricity.

In other prior art solutions (known for example from patent document U.S. Pat. No. 6,489,553), the temperature of photovoltaic panels is reduced by circulating a cooling fluid.

These solutions, however, have the disadvantage of requiring complex and expensive installations. Consequently, the costs and complication involved in cooling the panels does not compensate and in any case cancels out the benefits of higher panel efficiency due to lower temperature.

Moreover, none of the prior art systems is designed to reduce environmental impact, which involves a further disadvantage due to the need to install the systems in isolated areas which are inconvenient for the purposes of transmitting the electricity produced to the sites where the electricity is used.

### DISCLOSURE OF THE INVENTION

This invention has for an aim to provide an apparatus and a method that overcome the above mentioned disadvantages.

It is in particular an aim of the invention to provide a very high efficiency apparatus and method for converting solar energy into electricity and which is at once simple and inexpensive.

Another aim of the invention is to provide an apparatus and a method for generating electricity using photovoltaic panels that has a very low environmental impact.

These aims are fully achieved by the apparatus and method according to the invention as characterized in the appended claims.

More specifically, the apparatus according to the invention is characterized in that it comprises a panel mounting structure adapted to position the panels in a body of water in such a way that the top faces of the panels designed to receive the solar radiation are operatively covered by a layer of water of predetermined thickness.

In particular, the structure comprises a frame connected to the panels, at least one float connected to the frame and anchoring means to secure the frame to the bottom of the body of water.

The method according to this invention comprises the following steps:
preparing a structure for mounting the panels;
placing the structure in a body of water in such a way that the top faces of the panels designed to receive the solar radiation are operatively covered by a layer of water of predetermined thickness.

The method also comprises a step of varying the depth of the panels below the surface of the body of water, the panels being submerged in the water.

This invention thus provides a mounting structure especially designed to accommodate any photovoltaic system submerged in water or other liquid with a view to optimizing the efficiency of converting solar energy into electricity by submerging the panel, reducing the costs of producing this type of energy and at the same time reducing installation costs and environmental impact by using bodies of water (for example, artificial irrigation lakes, or natural or artificial bodies of water, including those made for purposes other than producing energy; bodies of water suitable for the purpose are, for example, artificial reservoirs or lakes, but the panels may also be installed in lagoons or other stretches of the sea sheltered from the waves; other places where the panels can be installed are pools, tanks or large solar thermal collectors).

The invention thus provides a mounting structure, or frame, that allows the photovoltaic panel (or the photovoltaic panels) to be placed under a layer of water (preferably having a thickness of between a few millimetres to approximately five centimetres).

### BRIEF DESCRIPTION OF THE DRAWINGS

These and other characteristics of the invention will become more apparent from the following detailed description of a preferred, non-limiting embodiment of it, with reference to the accompanying drawings, in which:

FIG. 1 illustrates an apparatus according to the invention;

FIG. 2 illustrates another embodiment of the apparatus of FIG. 1;

FIG. 3 illustrates a part of the apparatus of FIG. 1;

FIG. 4 illustrates the part of the apparatus of FIG. 3 connected with other similar parts to form a modular system;

FIG. 5 illustrates another embodiment of the part of the apparatus of FIG. 3;

FIG. 6 illustrates a portion of the part of FIG. 5;

FIG. 7 shows a graph representing the efficiency of an apparatus according to the invention, as a function of the spectral distribution of solar radiation;

FIG. 8 shows a graph representing the efficiency of an apparatus according to the invention, as a function of the thickness of the layer of water above the panels;

FIG. 9 shows a graph representing the voltage at maximum load of two photovoltaic panels, the first under standard conditions and the second below a layer of water according to the invention.

### DETAILED DESCRIPTION OF THE PREFERRED EMBODIMENTS OF THE INVENTION

The numeral 1 in the accompanying drawings denotes an apparatus according to the invention.

The apparatus 1 is an apparatus for generating electricity using photovoltaic panels 2.

The photovoltaic panels 2 are made according to known technology; each comprises a top face 3 designed to receive solar radiation in order to convert solar energy into electricity. The face 3 is composed of layers made of several possible materials such as silicon (monocrystalline, polycrystalline or amorphous), cadmium telluride, CIS (that is, copper-indium-selenium thin films) or polymer thin films.

According to the invention, the apparatus 1 comprises a panel 2 mounting structure 4 adapted for installing the panels 2 in a body of water in such a way that the top faces 3 of the panels 2 designed to receive the solar radiation is operatively covered by a layer of water of predetermined thickness.

Preferably, the structure 4 (for mounting the panels 2) comprises a frame 5 connected to at least one float 6 (preferably a plurality of floats 6) and secured to the bottom of the body of water by anchoring means such as ropes 7, for example.

It should be noted that in another embodiment, not illustrated, of the invention, the structure 4 is anchored directly to the bottom of the body of water and the floats 6 are not therefore required.

This embodiment, however, can be used only in bodies of water whose depth remains constant.

Generally speaking, therefore, the solution illustrated comprises the floats 6, since it can be installed in any body of water, even where the water depth varies.

In the context of the solution with the floats 6, the invention contemplates several different embodiments.

In a first embodiment, the panels 2 are connected to the frame 5 in such a way that they are submerged in the body of water and are therefore located at a predetermined depth below the water surface.

As regards the floats 6, the invention contemplates the provision of buoys 8 (permanently above the water surface) connected to the frame 5 by spacing members 9. Thus, the spacing members 9, consisting of rods for example, are interposed between the floats 6 and the frame 5.

Preferably, the apparatus also comprises at least one internally hollow element 10 connected to means (not illustrated, being per se known) for feeding fluids of different densities (for example air or water, alternately), into the elements 10.

The elements 10 thus constitute variable density sealed chambers.

The elements 10 in turn constitute floats 6 (when they are full of air or other fluid whose density is less than the density of water).

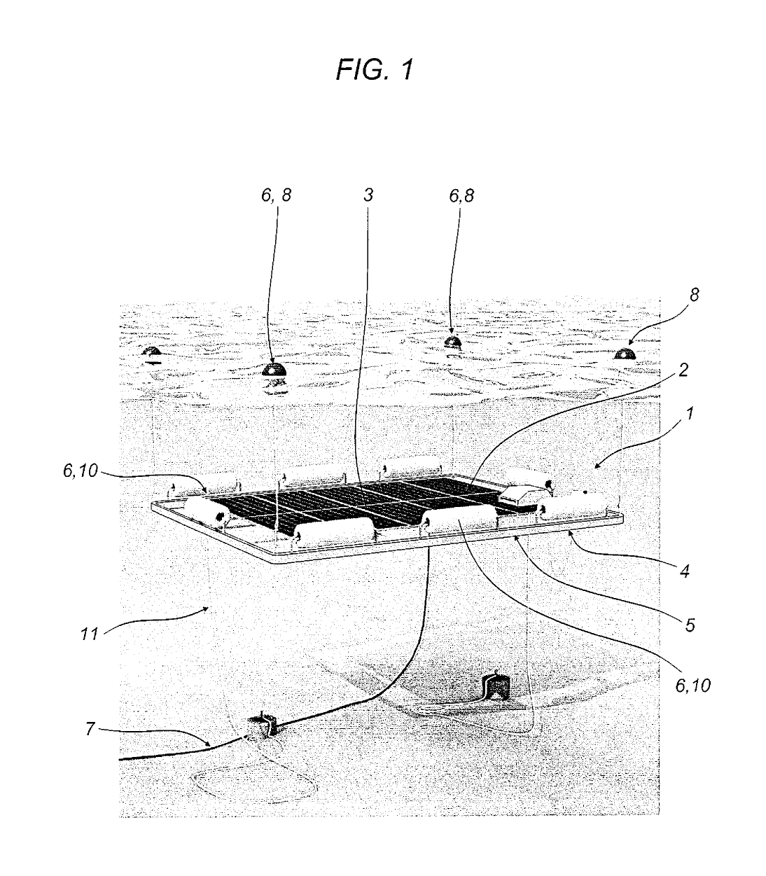

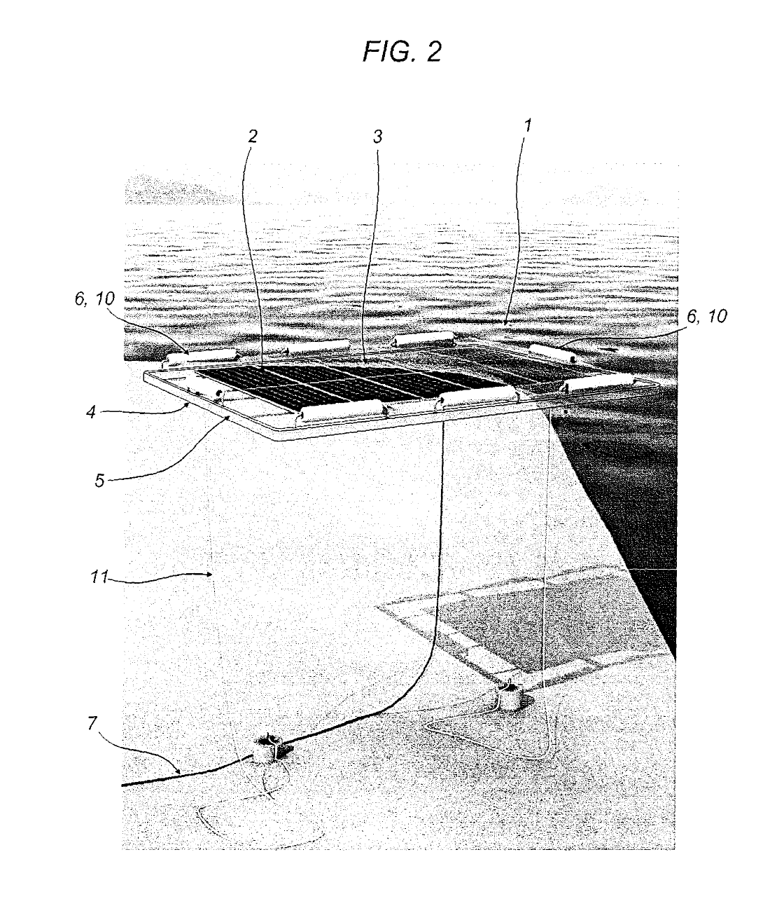

The elements 10 can therefore be connected to the frame 5 in addition to the buoys 8 (as in the example illustrated in FIG. 1) or instead of the buoys 8 (as in the example illustrated in FIG. 2).

The sealed chambers 10 (that is, the elements 10), together with the means for feeding the fluids of different density into the chambers, constitute means for varying the distance of the panels 2 (submerged in the body of water) from the surface of the water, that is to say, means for varying the depth of the panels 2.

Preferably, the apparatus 1 also comprises a control unit (not illustrated, consisting for example of an electronic card or a computer) connected to a panel 2 depth detector and to the variation means for automatically adjusting the depth of the panels in order to optimize the efficiency of energy conversion.

The detector, not illustrated, consists of a pressure gauge or any other known instrument for measuring the depth at which it is located under the water surface.

The control unit thus constitutes means for automatically adjusting (by feedback control) the depth of the panels and, hence, the thickness of the layer of water above the panels 2.

In the light of this, it should be noted that preferably the structure 4 is designed in such a way (that is, the adjustment means are programmed in such a way) that the thickness of the layer of water is between 1 and 2000 mm (and more preferably between 2 and 500 mm).

The panels 2 might, however, be placed at a greater depth (driving them further under the surface of the water) in the event of adverse weather conditions creating the risk of damage to the apparatus 1 (on account of strong waves for example).

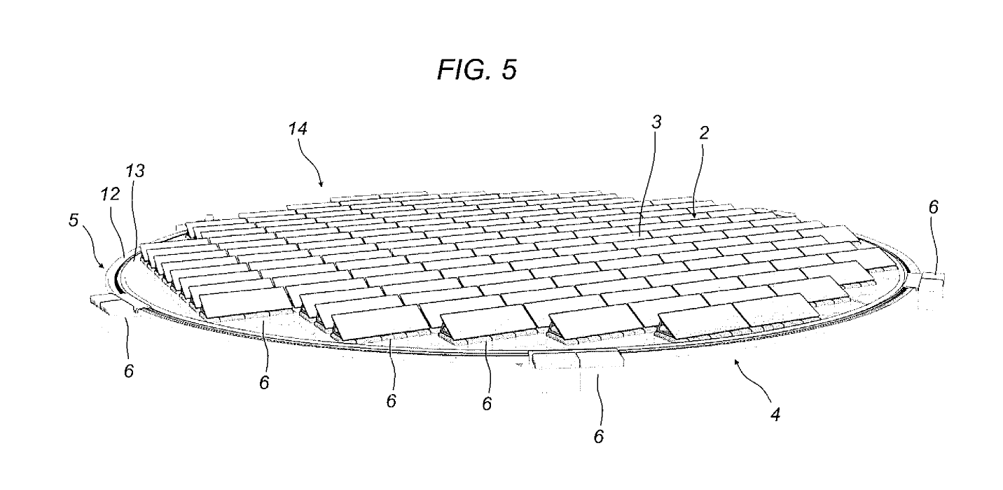

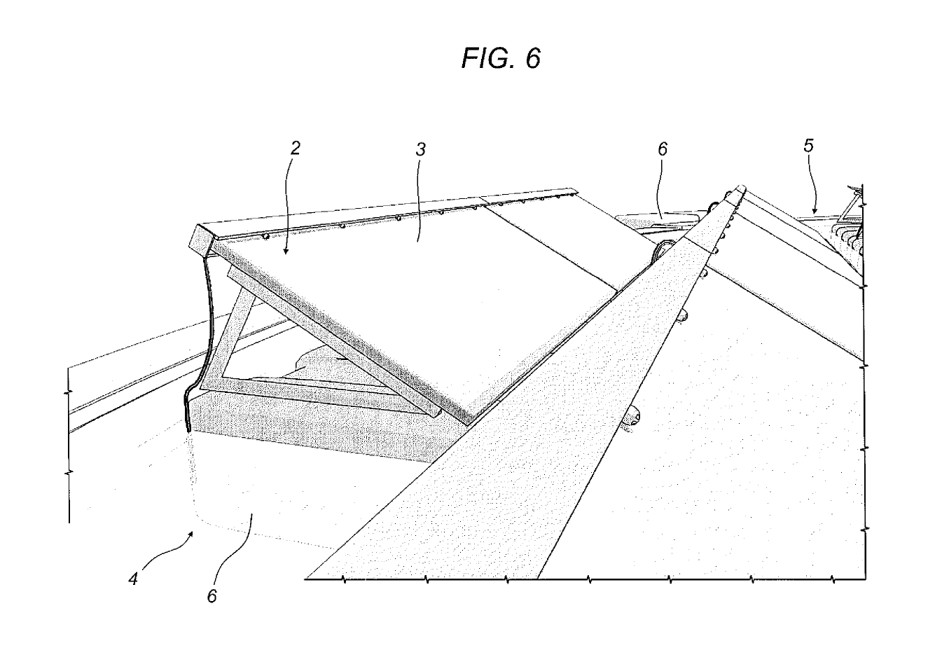

In a second embodiment (illustrated in FIGS. 5 and 6), the structure 4 is designed in such a way that the panels 2 emerge from the water, that is to say, they float on the surface of the water.

In that case, the apparatus 1 comprises a pumping device (of customary type and therefore not illustrated) designed to pump water from the body of water onto (causing it to flow over) the top faces 3 of the panels 2, thereby creating the above mentioned layer of water.

It should be noted that this embodiment is compatible both with the structure 4 of the type illustrated comprising the floats 6 (in such case, the floats 6 are in particular designed to allow the panels 2 to float on the surface of the water) and with the alternative type of structure 4 having feet securing it to the bottom of the body of water.

It should also be noted that the apparatus 1 comprises at least one electrical cable 11 for transferring the electrical power generated by the photovoltaic panels 2 to a load or to a power grid.

Irrespective of the embodiment adopted (with reference to the foregoing description), the apparatus 1 also contemplates the following, according to another aspect of the invention.

The panels 2 are movably associated with the frame 5, in such a way that they can be turned relative to the frame 5 about a vertical axis perpendicular to a horizontal plane defined by the surface of the body of water.

Further, the panels 2 are movably associated with the frame 5, in such a way that they can be inclined relative to the surface of the body of water (by rotating them about axes in a horizontal plane defined by the surface of the body of water.

In the light of this, the apparatus 1 preferably comprises drive means (not illustrated, consisting of customary electric motors, for example) associated with the frame 5 and operating on the panels 2 to rotate them about vertical axes and/or to incline them relative to the water surface.

The drive means are controlled by a control unit (such as the control unit mentioned above, for example) connected to a solar tracker (not illustrated, being per se known) in order to optimize the orientation of the panels 2 relative to the sun, thus maximizing the irradiation received by the panels 2.

It should be noticed that in the embodiment where the panels 2 rotate about both the vertical and the horizontal (that is, they can be inclined), the apparatus permits solar tracking with two degrees of freedom, allowing the maximum efficiency to be achieved. This obviously also involves higher production and running costs for the apparatus.

In the light of this, there is another embodiment of the apparatus 1 where the panels are inclined at a fixed angle or can be inclined about the horizontal between a limited number of predetermined positions (or angles): for example, a first optimized position for the winter season and a second optimized position for the summer season. This is in addition to the fact that the panels 2 can rotate about the vertical.

That way, costs are considerably lower than in the case of solar tracking on two axes (in effect, rotation about the vertical is facilitated by the fact that the panels 2 and the frame 5 itself are floating), but the efficiency is nevertheless high (though efficiency is lower than in the case of solar tracking on two axes, the reduction is relatively limited).

As regards the possibility of rotating the panels 2 about vertical axes relative to the frame 5, attention is drawn to the following.

The frame 5 preferably comprises:
a first portion 12 connected to the anchoring means 7;
a second portion 13 which the panels 2 are fixed to.

The second portion 13 of the frame 5 is rotatably connected to the first portion 12 in such a way as to rotate about a vertical axis perpendicular to the surface of the body of water, the panels being fixed to the second portion of the frame.

Preferably, the first portion 12 of the frame is circular in shape, that is to say, it comprises an annular member. The second portion 13 of the frame 5 is rotatably mounted in said annular member so that it can turn relative to the latter while remaining inside the annular member itself.

Preferably, the apparatus 1 is equipped with an actuator for automatically rotating the second portion 13 of the frame 5 (and the panels 2 as one with it) relative to the first portion 12.

The actuator (not illustrated, consisting, for example, of an electric motor) is connected to the control unit to adjust the orientation of the panels 2 relative to the inclination of the sun's rays, varying the inclination of the panels 2 with two degrees of freedom.

That advantageously allows the efficiency of the apparatus 1 to be further increased.

It should be noticed that since the structure 4 is equipped with floats 6, rotating the panels 2 about the vertical axis is particularly simple and economical.

In the light of this, it should be noted that the set of panels 2 associated with the frame 5 (that is, with the second portion 13 of the frame 5) constitute a floating unit 14.

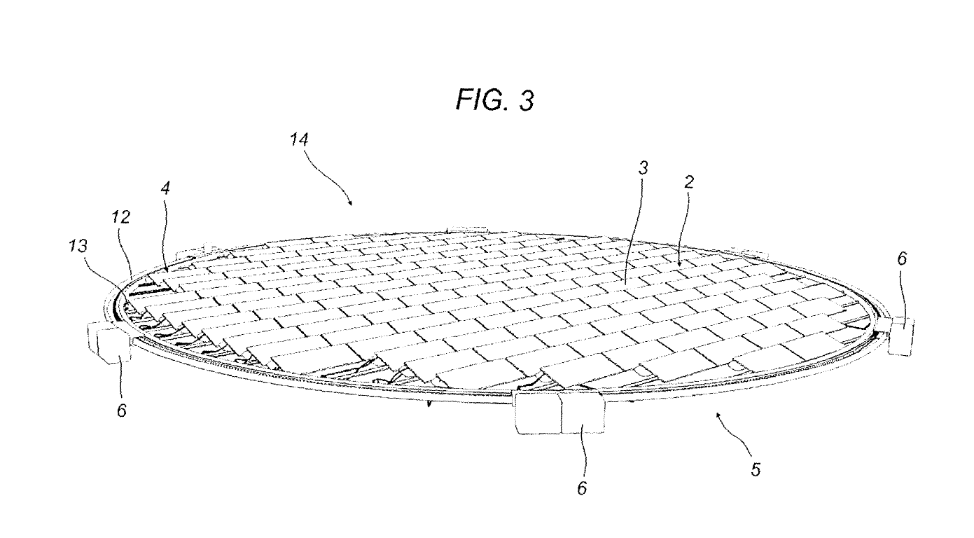

The floating unit 14 is illustrated for example in FIG. 3.

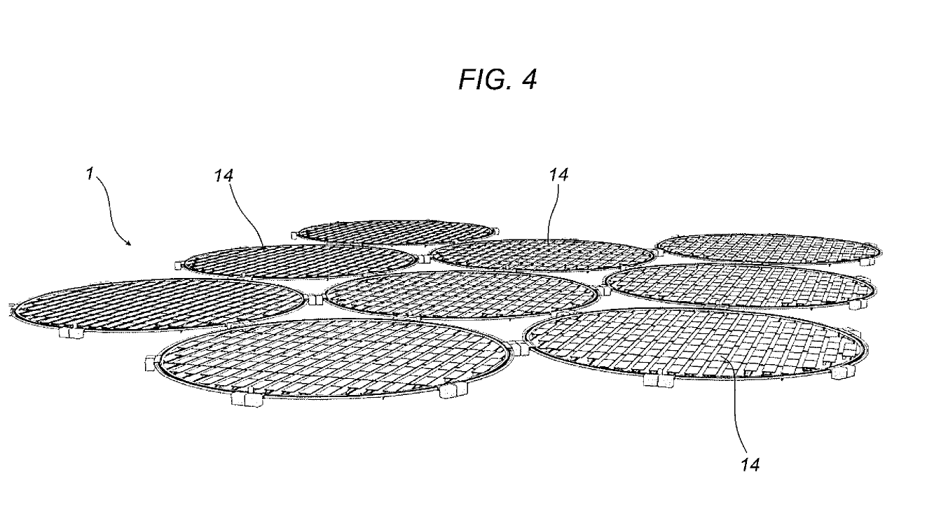

According to another aspect of the invention, the apparatus 1 comprises a plurality of interconnected floating units 14 forming a modular apparatus (illustrated in FIG. 4).

Preferably, in each of these units, the first portion 12 of the frame 5 is circular in shape and the second portion 13 is rotatably mounted in it.

This invention also addresses a method for generating electricity using photovoltaic panels 2.

The method comprises the following steps.
preparing a structure 4 for mounting the panels 2;
placing the structure 4 in a body of water in such a way that the top faces 3 of the panels designed to receive the solar radiation are operatively covered by a layer of water of predetermined thickness.

There is also a step of varying the depth of the panels 2 below the surface of the body of water, the panels 2 being submerged in the water. This enables the thickness of the water layer to be adjusted in order to optimize the efficiency of the apparatus 1.

In particular, this adjustment comprises the steps of:
measuring the above mentioned distance;
automatically adjusting the depth of the panels 2 in order to optimize the efficiency of energy conversion.

That comprises automatically selecting an optimum value of the thickness of the water layer above the panels according to the type of panel 2 (in particular, the type of material used to make its top face 3).

Preferably, the thickness is adjusted to a value of between 1 and 2000 mm.

Further, the method comprises a step of inclining the panels 2 relative to the surface of the body of water (or relative to the frame 5 and, preferably, relative to the first portion 12 of the frame 5), the panels 2 being movably connected to the mounting frame 5 (preferably to the first portion 12 of the frame 5).

Alternatively, in the method according to the invention, the panels might be positioned at a fixed angle relative to the horizontal or they might be moved between a limited number of predetermined positions corresponding to different set angles (for example, optimized for different times of the year).

The method also comprises a step of turning the frame 5 (more specifically, the second portion 13 of the frame 5) and of the panels 2 associated with it about an axis (vertical) perpendicular to the surface of the body of water.

The step of turning about the vertical axis (or line) is contemplated not only in the case where the panels 2 are also inclined at an angle to the horizontal but also in the case where the panels 2 are inclined at a fixed angle or at a variable angle between a number of predetermined positions (corresponding to a limited number of set angles).

In another embodiment, where the panels 2 are not kept submerged under the surface of the water, the method comprises a step of pumping water from the body of water onto the top faces 3 of the panels 2 to create the above mentioned layer of water, the panels 2 being located above the surface of the water (more specifically, the panels 2 are located on the frame 5 which is mounted on a plurality of floats 6).

This embodiment is compatible with all the above described steps of moving the panels 2 relative to the frame 5 in order to optimize their orientation with respect to the sun's rays.

According to another aspect of this invention, the method comprises a step of connecting a plurality of floating units 14 connectable to each other to form a modular apparatus. Each of the units 14 preferably comprises a first circular frame portion 12 and a second frame portion 13 rotatably coupled to it and connected to the photovoltaic panels 2.

This aspect of the invention (modular system) is compatible and synergically combined with all the other aspects of the invention.

It should be noted that the frame 5 is made preferably of a lightweight material, for example a polymeric material, that supports a number of panels variable from 10 to 100. The entire panel system may be positioned at variable depths, for example 5 to 10 cm, as described above (preferably by means of the floats 6 and anchored to a weight on the bottom of the body of water).

This invention considerably improves the efficiency of the apparatus for generating electricity using photovoltaic panels.

Indeed, numerous research studies and experiments conducted by the Applicant, described briefly below in support of the foregoing description, have demonstrated the advantages of the invention (with particular reference to the configurations preferred according to the type of panel used).

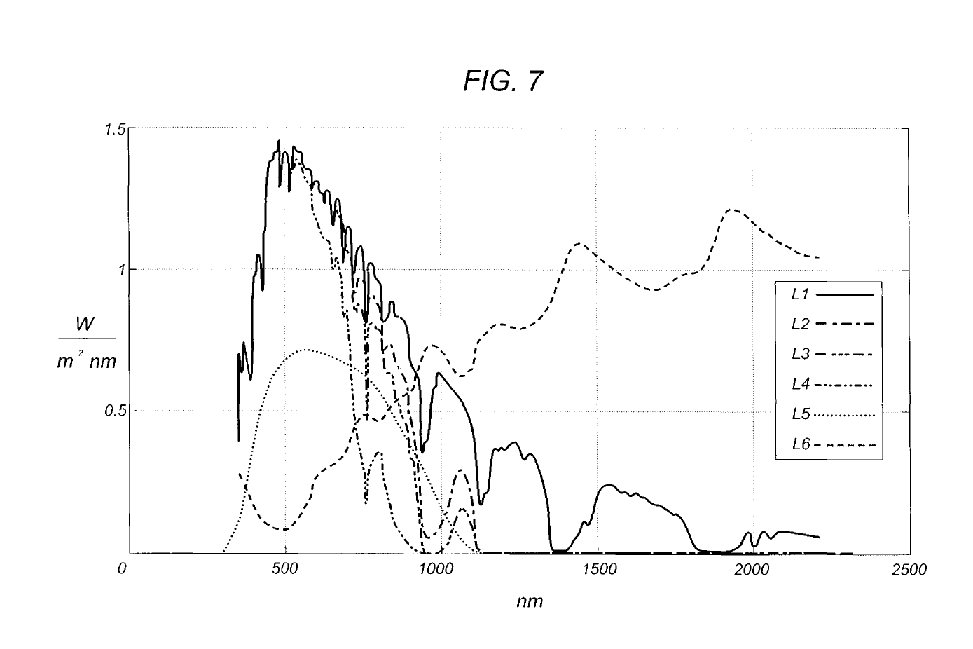

The graph of FIG. 7 shows the solar spectrum at different water depths (the curves L1, L2, L3 and L4 refer to the depths of 0 cm, 5 cm, 10 cm and 50 cm, respectively) and the curve L5 the monocrystalline silicon absorption: the spectral power received by a panel (in Watt/nm/m²) is shown on the y-axis and the wavelength, in nm, on the x-axis The silicon efficiency curve is given in arbitrary units.

As may be observed in the graph, the water layer thickness of 5 centimetres absorbs approximately 30% of the solar radiation without substantially altering the conversion capacity of the silicon. In particular, the water's absorption curve is labelled L6.

The minor reduction is amply compensated by the improved efficiency obtainable by keeping the silicon at relatively low temperatures.

More in detail, the higher efficiency was studied by the Applicant in the course of in-depth research and experiments and is due to the following two factors:

a) Lower input impedance of the solar radiation which meets along its path a layer of water with a refraction index n=1.33. This intermediate layer facilitates the sunlight's penetration at a level of 2% for direct and vertical light, and at a level of 4-6% for diffuse light or direct light at angles of incidence greater than 50°.

b) An effect of stabilizing the temperature, or (effectively) thermostatizing, the panel which operates at the temperature of the water in the range of 10-30° C. and is not therefore subject to thermal drift, which can be very high especially in summer. This effect may vary from one panel to another but is always quite marked: if the operating temperature of an out-of-water panel is 75° C. (as is often the case in full sunlight) the loss of efficiency is 25% for mono or polycrystalline silicon, 15% for cadmium telluride and 10% for amorphous silicon.

This loss of efficiency is avoided by the solution provided by this invention.

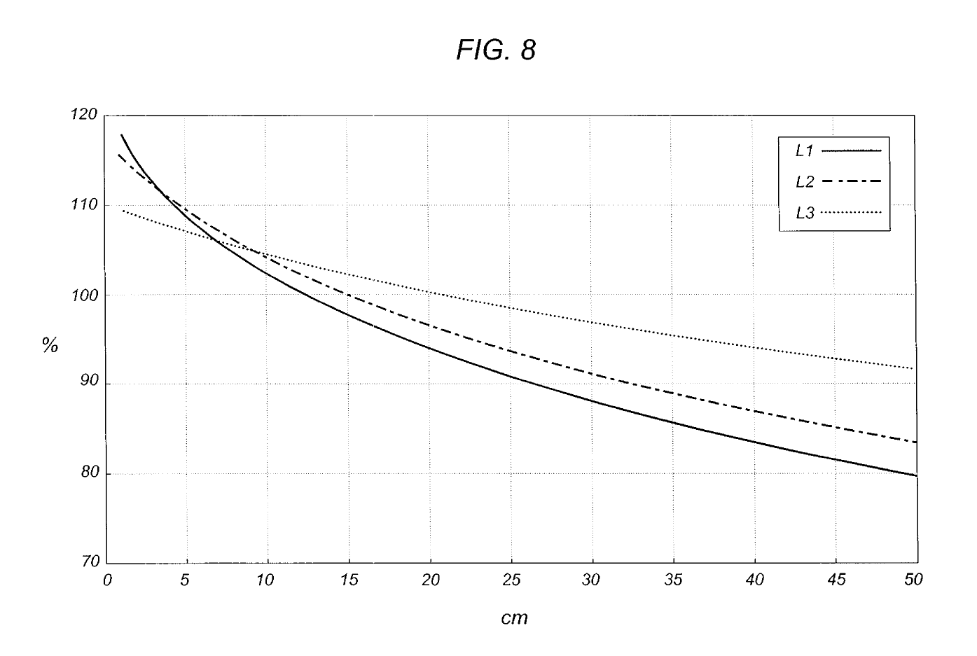

FIG. 8 shows the simulated efficiency of a submerged panel compared to the efficiency of a panel under conditions of normal exposure, multiplied by 100. It should be noted that all the panels examined can advantageously be placed under 10 cm of water and that, in the case of amorphous silicon, the depth may be even more than 50 cm.

In particular, FIG. 8 illustrates the efficiency curves (as a function of the thickness of the water layer above the top face 3 of the panel 2) for three types of panels characterized by the following materials: monocrystalline silicon (curve L1), polycrystalline silicon (curve L2) and amorphous silicon (curve L3).

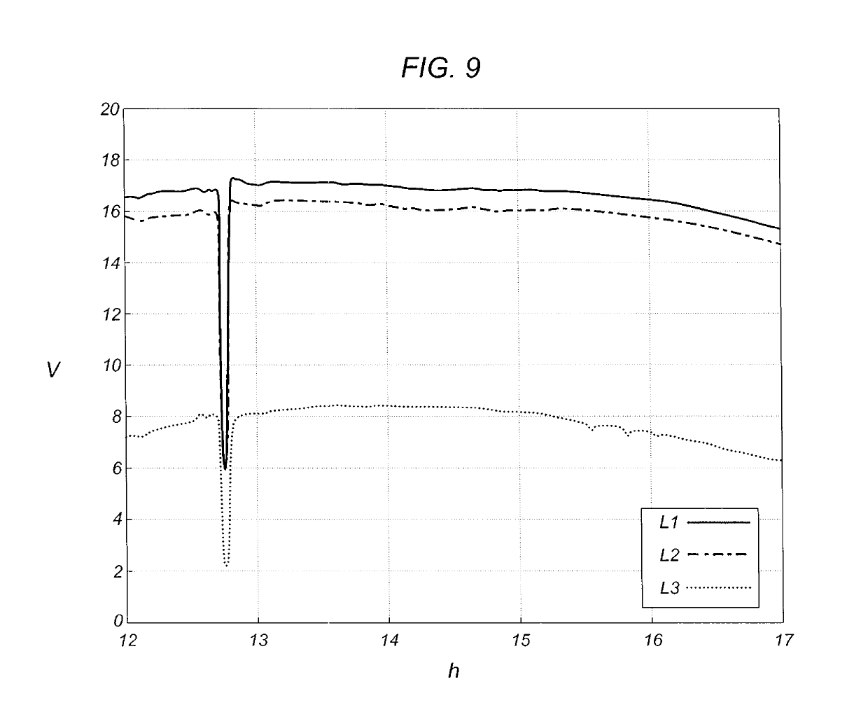

In addition, numerous comparative acquisitions were performed and an example is provided in FIG. 9, showing the values of voltage measured (at optimum load) for two panels made of monocrystalline silicon: one without the layer of water above the top face 3 of the panel (curve L2) and one submerged in 5 cm of water (curve L1), that is, having a 5 cm layer of water above it.

Also shown is the curve of incident radiation (divided by 100 for reasons of graphical representation), labelled L3. The average temperature difference between the two panels is 30° C. and the increase in efficiency found is greater than 10%, in line with the results of the simulations.

The invention thus achieves the following advantages.

First of all, the invention makes it possible to improve the efficiency of commercial photovoltaic panels by at least 10%.

The invention also notably reduces installation and operating costs.

Moreover, the invention reduces the environmental impact of large installations since the panels, submerged in a body of water, are not visible from the outside.

The invention is also easy to maintain. In effect, the panels can be cleaned using robots already available on the market such as, for example, automatic self-propelled systems for cleaning swimming pools.

Lastly, the invention guarantees better security for photovoltaic installations, which are often exposed to theft or acts of vandalism.

1. An apparatus (1) for generating electricity using photovoltaic panels (2), having:
a panel (2) mounting structure (4) adapted to position the panels in a body of water in such a way that the top faces (3) of the panels (2) designed to receive the solar radiation are operatively covered by a layer of water of predetermined thickness;
a frame (5) connected to the panels (2);
at least one float (6) connected to the frame (5);
anchoring means (7) for securing the frame (5) to the bottom of the body of water, wherein the frame (5) comprises a first portion (12) connected to the anchoring means (7) and a second portion (13) rotating relative to the first portion (12) about an axis perpendicular to the surface of the body of water, the panels (2) being fixed to said second portion (13) of the frame (5), to be movably connected to the first portion (12) of the mounting frame (5) to rotate about said axis; and in that the apparatus comprises drive means associated with the frame (5) for automatically rotating the second portion (13) of the frame (5) and the panels (2) as one with it about said axis perpendicular to the water surface.

2. The apparatus according to claim 1, comprising means for varying the distance of the panels (2) submerged in the body of water from the surface of the water.

3. The apparatus according to claim 2, wherein said means for varying the depth of the panels (2) comprise one or more sealed chambers (10) connected to means for feeding fluids of different density into the chambers (10).

4. The apparatus according to claim 2, comprising a control unit connected to a depth detector and to the variation means for automatically adjusting the depth of the panels (2) in order to optimize the efficiency of energy conversion.

5. The apparatus according to claim 1, wherein the first frame portion (12) is annular in shape.

6. The apparatus according to claim 1, comprising drive means associated with the frame (5) and operating on the panels (2) to incline them with respect to the water surface, the panels being movably connected to the mounting frame (5) so that they can be inclined by rotation about axes parallel to the water surface.

7. The apparatus according to claim 1, wherein the panels (2) are positioned relative to the frame (5) at a fixed angle to the water surface or are movable by rotation about axes parallel to the water surface between a set number of predetermined angled positions.

8. The apparatus according to claim 1, comprising a plurality of floating units (14) connected to each other to form a modular apparatus, the first frame portion (12) of each of said units being annular in shape and the second portion (13) being rotatably mounted in it.

9. The apparatus according to claim 1, comprising a pumping device designed to pump water from the body of water onto the top faces (3) of the panels (2), thereby creating said layer of water, the structure (4) being designed to keep the panels (2) above the surface of the water.

10. The apparatus according to claim 1, wherein the layer of water has a thickness that may vary in a range between 1 and 2000 mm.

11. A method for generating electricity using photovoltaic panels (2), comprising the following steps:
preparing a structure (4) for mounting the panels (2);
placing the structure (4) in a body of water in such a way that the top faces (3) of the panels (2) designed to receive the solar radiation are operatively covered by a layer of water of predetermined thickness;
turning at least a portion (13) of the frame (5) and the panels (2) associated with it about an axis perpendicular to the surface of the body of water.

12. The method according to claim 11, comprising a step of varying the distance of the panels (2) from the surface of the body of water, the panels (2) being submerged in the water.

13. The method according to claim 12, comprising the steps of:
measuring said distance;
automatically adjusting the depth of the panels (2) in order to optimize the efficiency of energy conversion.

14. The method according to claim 11, comprising a step of inclining the panels (2) relative to the surface of the body of water, the panels being movably connected to the mounting frame (5) or being movable between predetermined inclined positions or being positioned at a fixed angle to the frame (5).

15. The method according to claim 11, comprising a step of pumping water from the body of water onto the top faces (3) of the panels (2), thereby creating said layer of water, the panels (2) being positioned above the surface of the water.

16. The method according to claim 11, wherein the layer of water has a thickness that may vary in a range between 1 and 2000 mm.

17. The method according to claim 11, comprising a step of connecting a plurality of floating units (14) to each other to form a modular apparatus, the first portion (12) of the frame (5) of each of said units (14) being annular in shape and the second portion (13) of the frame (5) being rotatably mounted in it and connected to the photovoltaic panels (2).
